(19) United States
(12) Patent Application Publication
(10) Pub. No.: US 2017/0201064 A1
(43) Pub. Date: Jul. 13, 2017

(54) METHOD OF MANUFACTURING SEMICONDUCTOR LASER ELEMENT

(71) Applicant: Mitsubishi Electric Corporation, Tokyo (JP)

(72) Inventor: Hitoshi SAKUMA, Tokyo (JP)

(73) Assignee: Mitsubishi Electric Corporation, Tokyo (JP)

(21) Appl. No.: 15/292,181

(22) Filed: Oct. 13, 2016

(30) Foreign Application Priority Data
Jan. 8, 2016 (JP) 2016-002883

(51) Int. Cl. H01S 5/02; H01S 5/227; H01S 5/028

(52) U.S. Cl. CPC H01S 5/0201; H01S 5/028; H01S 5/0203; H01S 5/2275

(57) ABSTRACT

A method of manufacturing a semiconductor laser element includes an element formation step of forming a plurality of semiconductor laser elements in a central portion of a wafer, the wafer including the central portion and a peripheral portion surrounding the central portion, a plating step of forming a plated layer having a groove in the form of a grid on a lower surface of the peripheral portion and not forming the plated layer on a lower surface of the central portion, a laser bar step of forming a laser bar by cutting off part of the central portion, and a singulation step of singulating the laser bar to form semiconductor laser elements.

### BACKGROUND OF THE INVENTION

Field of the Invention

The present invention relates to a method of manufacturing a semiconductor laser element for use in, for example, an optical network.

Background Art

In recent years, ultra-high-speed, large-volume, high-efficiency optical network infrastructure development for large-volume data transfer has become necessary in trunk lines and access lines. Semiconductor laser elements used as light sources therein are required to have increased speed. To increase the speed of semiconductor laser elements, relaxation oscillation frequencies need to be improved. A relaxation oscillation frequency is an indicator of whether laser light can follow an electrical waveform, and can be improved by employing a short resonator length. Japanese Patent Application Publication No. H06-295848 discloses a method of manufacturing a semiconductor laser element. In this manufacturing method, a wafer is cleaved to form bars, each including a line of chips parallel to the longitudinal direction, and then each bar is divided into semiconductor laser elements.

Electrodes are formed on a wafer having a plurality of semiconductor laser elements formed therein. Then, the wafer is processed into bar-shaped pieces. The bar-shaped pieces thus obtained are referred to as laser bars. By singulating the laser bars, individual semiconductor laser elements can be obtained. It should be noted that a semiconductor laser element means a laser diode.

In the case where a semiconductor laser element having a short resonator length is manufactured, a laser bar easily bows. For example, in the case where a resonator length is as short as 150 μm, a laser bar after cleaving has a bow of 100 μm or more. The bowing of the laser bar makes chips having semiconductor laser elements formed therein prone to scatter when the laser bar is cleaved to obtain semiconductor laser elements.

To reduce the amount of bowing of the laser bar, eliminating plating on a lower-surface side of the wafer is effective. However, this causes another problem of the easy breaking of the wafer.

### SUMMARY OF THE INVENTION

The present invention has been accomplished to solve the above-described problems, and an object of the present invention is to provide a method of manufacturing a semiconductor laser element which can reduce wafer breaking and laser bar bowing.

The features and advantages of the present invention may be summarized as follows.

According to one aspect of the present invention, a method of manufacturing a semiconductor laser element includes an element formation step of forming a plurality of semiconductor laser elements in a central portion of a wafer, the wafer including the central portion and a peripheral portion surrounding the central portion, a plating step of forming a plated layer having a groove in the form of a grid on a lower surface of the peripheral portion and not forming the plated layer on a lower surface of the central portion, a laser bar step of forming a laser bar by cutting off part of the central portion, and a singulation step of singulating the laser bar to form semiconductor laser elements.

According to another aspect of the present invention, a method of manufacturing a semiconductor laser element includes an element formation step of forming a plurality of semiconductor laser elements in a central portion of a wafer, the wafer including the central portion and a peripheral portion surrounding the central portion, a wet etching step of wet-etching a lower surface of the central portion and not wet-etching a lower surface of the peripheral portion to make the central portion thinner than the peripheral portion and form a trench extending toward an upper surface of the wafer on a boundary between the central portion and the peripheral portion, a laser bar step of forming a laser bar by cutting off part of the central portion, and a singulation step of singulating the laser bar to form semiconductor laser elements, wherein in the laser bar step, the wafer is split along the trench.

Other and further objects, features and advantages of the invention will appear more fully from the following description.

### BRIEF DESCRIPTION OF THE DRAWINGS

FIG. 1 is a view showing a lower-surface structure of a wafer;

FIG. 2 is a partial cross-sectional view of the central portion;

FIG. 3 is a view showing an example of cleaving positions;

FIG. 4 is a view showing a bottom surface and a cross section of a wafer after the wet etching step; and

FIG. 5 shows an electrode formed on the lower surface of the wafer.

### DETAILED DESCRIPTION OF THE PREFERRED EMBODIMENTS

Semiconductor laser element manufacturing methods according to embodiments of the present invention will be described with reference to the drawings. The same or corresponding components will be denoted by the same reference signs, and the repetition of explanation thereof may be omitted.

### Embodiment 1

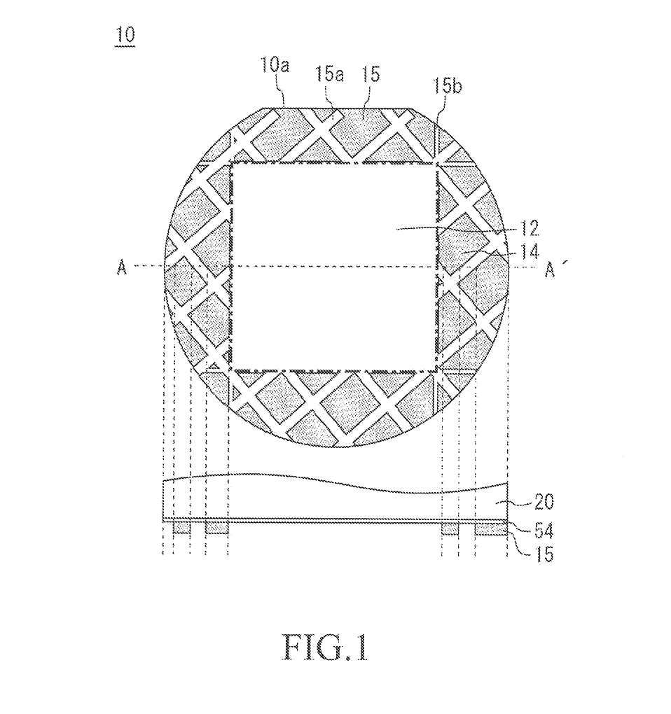

In a method of manufacturing a semiconductor laser element according to Embodiment 1 of the present invention, first, a plurality of semiconductor laser elements are formed in a wafer. FIG. 1 is a view showing a lower-surface structure of a wafer 10. An upper part of FIG. 1 is a bottom view of the wafer 10, and a lower part thereof is a cross-sectional view taken along line A-A′. The wafer 10 includes a central portion 12 and a peripheral portion 14 surrounding the central portion 12. The central portion 12 is a region surrounded by dash-dot lines. A plurality of semiconductor laser elements are formed in the central portion 12. This step is referred to as an element formation step.

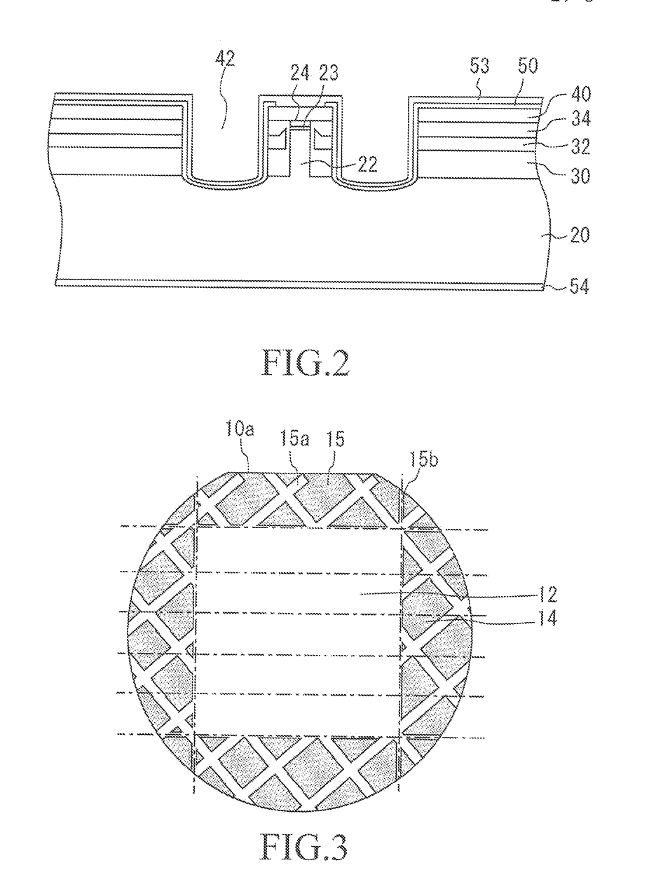

FIG. 2 is a partial cross-sectional view of the central portion 12 after the element formation step. In the element formation step, a semiconductor laser element shown in FIG. 2 is formed using a semiconductor process. This semiconductor laser element will be described. A mesa stripe structure, which includes a lower cladding layer 22 of a first conductivity type, an active layer 23, and an upper cladding layer 24 of a second conductivity type stacked on top of each other, is provided on a semiconductor substrate 20. Current blocking layers, each of which includes a layer 30 of the first conductivity type, a layer 32 of the second conductivity type, and a layer 34 of the first conductivity type stacked on top of each other, are provided to the right and left of the mesa stripe structure.

A contact layer 40 of the second conductivity type is provided above the mesa stripe structure and the current blocking layers. Grooves 42 reaching the semiconductor substrate 20 are provided to the right and left of the mesa stripe structure. An insulating film 50 is formed which covers the mesa stripe structure with the contact layer 40 above the active layer 23 exposed. This insulating film 50 covers, in addition to the mesa stripe structure, bottom surfaces of the grooves 42 and the current blocking layers located across the mesa stripe structure from each other with the grooves 42 interposed therebetween. An electrode 53 is formed which is in contact with the contact layer 40 above the active layer 23. Moreover, an electrode 54 of the first conductivity type is formed on a lower surface of the semiconductor substrate 20.

A plurality of semiconductor laser elements such as described above are formed in the central portion 12. It should be noted that the specific configuration of the semiconductor laser element is not limited to one shown in FIG. 2, and any well-known configuration can be employed.

Then, the process is moved to a plating step. In the plating step, a plated layer is formed on the lower surface of the wafer 10. Specifically, as shown in FIG. 1, a plated layer 15 having grooves 15a in the form of a grid is formed on a lower surface of the peripheral portion 14, and no plated layer 15 is formed on a lower surface of the central portion 12. The plated layer 15 is made of, for example, Au, Cu, Pd, or Ni. Preferably, there is no plating in regions having the grooves 15a formed therein. However, slight plating is acceptable.

The grooves 15a are formed non-parallel to crystal directions of the wafer 10. In other words, the grooves 15a are formed neither parallel nor perpendicular to an orientation flat 10a of the wafer 10. Preferably, the grooves 15a are formed at an angle of 45° with respect to the crystal directions of the wafer 10. The word “crystal direction” means a direction along which the wafer 10 is cleaved.

Preferably, grooves 15b for cutting are formed in the plated layer 15 in the plating step. The grooves 15b for cutting are formed parallel to the crystal directions of the wafer 10. In other words, the grooves 15b for cutting are grooves parallel or perpendicular to the orientation flat 10a of the wafer 10. FIG. 1 shows the grooves 15b for cutting formed to be narrower than the grooves 15a.

Then, the process is moved to a laser bar step. In the laser bar step, part of the central portion 12 is cut off to form a laser bar. More specifically, in the laser bar step, semiconductor laser elements formed in the central portion 12 are cut out from the peripheral portion 14 in the form of a laser bar by cleaving. A laser bar is a bar having a plurality of semiconductor laser elements arranged in an array. FIG. 3 is a view showing an example of cleaving positions. For example, the wafer 10 is cleaved along dash-dot lines to prepare a plurality of laser bars. The width of a laser bar is equal to the resonator length of a semiconductor laser element. The resonator length of the semiconductor laser element according to Embodiment 1 of the present invention is, for example, 150 μm or less.

In this laser bar step, if the wafer is cut along the aforementioned grooves 15b for cutting, the absence of the plated layer 15 makes cleaving smooth. It should be noted that this does not apply to the case where no grooves 15b for cutting are formed.

Then, the process is moved to a singulation step. In the singulation step, each laser bar is singulated to form semiconductor laser elements. The method of manufacturing the semiconductor laser element according to Embodiment 1 of the present invention includes the above-described steps.

In the method of manufacturing the semiconductor laser element according to Embodiment 1 of the present invention, since the plated layer 15 formed on the lower surface of the wafer 10 reinforces the wafer 10, the breaking of the wafer 10 can be reduced. Thus, yields can be improved. Since the plated layer 15 is formed only in the peripheral portion 14 of the wafer 10, laser bars without the plated layer 15 can be obtained. Accordingly, even if laser bars are long and narrow because of a short resonator length of, for example, 150 μm or less, laser bar bowing can be reduced.

Since the grooves 15a are formed in the plated layer 15, the amount of plating used can be made smaller than in the case where no grooves 15a are formed, and cost can be reduced. Supposing that grooves are formed parallel to the crystal directions of the wafer 10, the wafer breaks along the grooves because the wafer is prone to break along the crystal directions. However, in Embodiment 1 of the present invention, since the grooves 15a are formed non-parallel to the crystal directions of the wafer 10, the plated layer 15 reduces the breaking of the wafer 10 in the crystal directions. Accordingly, the plated layer 15 can reduce the breaking of the wafer 10 while providing the grooves 15a reduces the amount of plating used.

Various modifications can be made to the method of manufacturing the semiconductor laser element according to Embodiment 1 of the present invention. For example, the grooves 15b for cutting may be omitted. The plane shape of the grooves 15a is not particularly limited as long as the plane shape thereof is in the form of a grid for reducing the amount of plating used. Grooves do not necessarily need to be formed in linear shapes. If only a reduction in the amount of plating used is desired, the grooves 15a do not need to be formed non-parallel to the crystal directions of the wafer 10.

These modifications can be appropriately applied to a method of manufacturing a semiconductor laser element according to an embodiment below. It should be noted that the method of manufacturing the semiconductor laser element according to the embodiment below have many things in common with that of Embodiment 1, and differences from Embodiment 1 will therefore be mainly described.

### Embodiment 2

In a method of manufacturing a semiconductor laser element according to Embodiment 2, an element formation step is performed as in Embodiment 1. This element formation step is approximately the same as that of Embodiment 1, but differs from that of Embodiment 1 in that no electrode is formed on a lower-surface side of a wafer.

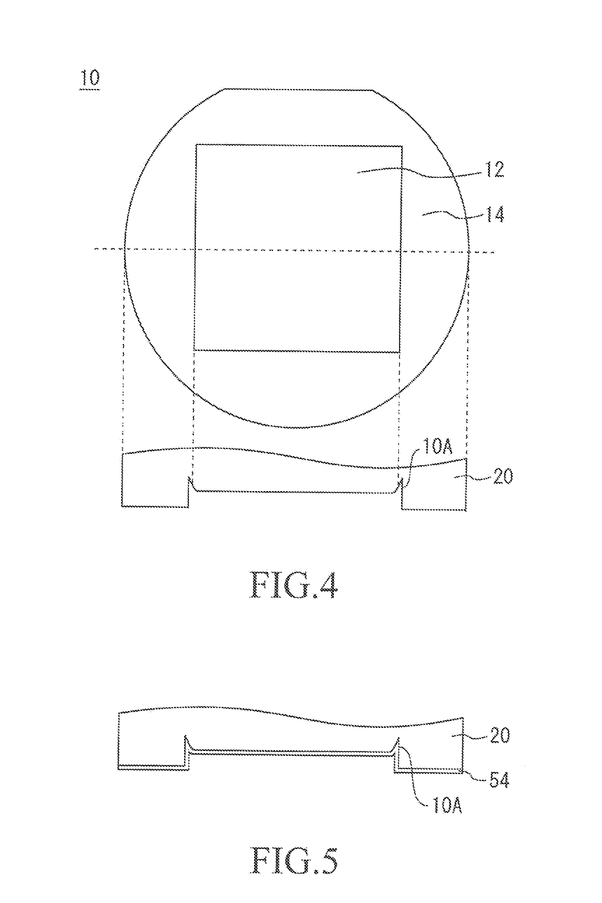

After the element formation step is carried out, a wet etching step is carried out. FIG. 4 is a view showing a bottom surface and a cross section of a wafer after the wet etching step. In the wet etching step, the lower surface of the central portion 12 is wet etched, but the lower surface of the peripheral portion 14 is not wet etched. Thus, the central portion 12 is made thinner than the peripheral portion 14, and a trench 10A extending toward the upper surface of the wafer 10 is formed on a boundary between the central portion 12 and the peripheral portion 14.

For example, the lower surface of the central portion 12 is etched using a liquid chemical containing Br with a mask formed on the lower surface of the peripheral portion 14. As a material for the semiconductor substrate 20, a well-known substrate material such as InP, GaAs, or GaN can be used. After the wet etching step, an electrode is formed on the lower surface of the wafer 10. FIG. 5 is a view showing a state in which the electrode 54 of the first conductivity type has been formed on the lower surface of the wafer 10.

Then, the process is moved to a laser bar step, and part of the central portion 12 is cut off to form laser bars. Cleaving in the laser bar step includes wafer cleaving along the aforementioned trench 10A. Then, the process is moved to a singulation step, and each laser bar is singulated to form semiconductor laser elements.

In the method of manufacturing the semiconductor laser element according to Embodiment 2 of the present invention, the wet etching step is performed such that only the central portion 12 of the wafer 10 is thinned and that the peripheral portion 14 is not etched. Accordingly, the peripheral portion 14 left unthinned enables the strength of the wafer 10 to be maintained, and wafer breaking can therefore be reduced. Moreover, since the lower-surface side of the wafer is not plated, laser bar bowing can be reduced. The absence of plating reduces cost. Further, since the trench 10A formed in the wet etching step facilitates cleaving in the laser bar step, yields are improved.

Features of Embodiments 1 and 2 may be appropriately combined. For example, in the method of manufacturing the semiconductor laser element of Embodiment 1, the wet etching step of Embodiment 2 may be carried out before the laser bar step to form a trench. Cleaving along the trench can improve yields.

In one aspect of the present invention, a plated layer with grooves is formed in a peripheral portion which is a region having no semiconductor laser elements formed therein. In another aspect of the present invention, a trench for facilitating cleaving is formed with the thickness of the peripheral portion maintained. Thus, wafer breaking and laser bar bowing can be reduced.

Obviously many modifications and variations of the present invention are possible in the light of the above teachings. It is therefore to be understood that within the scope of the appended claims the invention may be practiced otherwise than as specifically described.

What is claimed is:

1. A method of manufacturing a semiconductor laser element, comprising:
an element formation step of forming a plurality of semiconductor laser elements in a central portion of a wafer, the wafer including the central portion and a peripheral portion surrounding the central portion;
a plating step of forming a plated layer having a groove in the form of a grid on a lower surface of the peripheral portion and not forming the plated layer on a lower surface of the central portion;
a laser bar step of forming a laser bar by cutting off part of the central portion; and
a singulation step of singulating the laser bar to form semiconductor laser elements.

2. The method according to claim 1, wherein the groove is formed non-parallel to a crystal direction of the wafer.

3. The method according to claim 2, wherein the groove is formed at an angle of 45° with respect to the crystal direction of the wafer.

4. The method according to claim 1,
wherein in the plating step, a groove for cutting is formed in the plated layer, and
in the laser bar step, the wafer is cut along the groove for cutting.

5. The method according to claim 1, wherein the plated layer is made of any one of Au, Cu, Pd, and Ni.

6. A method of manufacturing a semiconductor laser element, comprising:
an element formation step of forming a plurality of semiconductor laser elements in a central portion of a wafer, the wafer including the central portion and a peripheral portion surrounding the central portion;
a wet etching step of wet-etching a lower surface of the central portion and not wet-etching a lower surface of the peripheral portion to make the central portion thinner than the peripheral portion and form a trench extending toward an upper surface of the wafer on a boundary between the central portion and the peripheral portion;
a laser bar step of forming a laser bar by cutting off part of the central portion; and
a singulation step of singulating the laser bar to form semiconductor laser elements,
wherein in the laser bar step, the wafer is split along the trench.

7. The method according to claim 6, wherein a liquid chemical used in the wet etching step contains Br.

8. The method according to claim 6, wherein after the wet etching step, before the laser bar step, an electrode is formed on a lower surface of the wafer.

9. The method according to claim 1, wherein the semiconductor laser element comprises a mesa stripe structure comprising an active layer, and current blocking layers formed to right and left of the mesa stripe structure.

10. The method according to claim 1, wherein the semiconductor laser element has a resonator length of 150 μm or less.
